(19) United States
(12) Patent Application Publication
(10) Pub. No.: US 2022/0299559 A1
(43) Pub. Date: Sep. 22, 2022

(54) METHOD FOR DETERMINING A CET MAP, METHOD FOR DETERMINING THE ACTIVATION ENERGY OF A TYPE OF DEFECT AND ASSOCIATED DEVICE

(71) Applicant: COMMISSARIAT À L'ÉNERGIE ATOMIQUE ET AUX ÉNERGIES ALTERNATIVES, Paris (FR)

(72) Inventors: Abygael VIEY, GRENOBLE CEDEX 09 (FR); Xavier GARROS, GRENOBLE CEDEX 09 (FR); Louis GERRER, GRENOBLE CEDEX 09 (FR); William VANDENDAELE, GRENOBLE CEDEX 09 (FR)

(21) Appl. No.: 17/697,147

(22) Filed: Mar. 17, 2022

(30) Foreign Application Priority Data
Mar. 18, 2021 (FR) 2102722

(51) Int. Cl. G01R 31/26

(52) U.S. Cl. CPC G01R 31/2601; G01R 31/2607

(57) ABSTRACT

A method for determining a CET mapping characterizing the capture and emission time of traps in a transistor for a given stress voltage and a given temperature, called an optimal CET mapping, this determination being made from an experimental measurement of the time course of the change in the threshold voltage V_TH for the same stress voltage and the same temperature and from a distribution function of the traps, the distribution function may be defined by N_par parameters. More particularly, the method implements a genetic algorithm whose parameters are regularly updated in order to optimize the computation time while decreasing the risk of reaching a local minimum in the determination of the optimal CET mapping.

### TECHNICAL FIELD OF THE INVENTION

The technical field of the invention is the characterization of defects in a semiconductor device.

The present invention relates to a method for determining a CET mapping, in particular a method for automating this determination by means of a genetic algorithm. The invention also relates to a method for determining the activation energy of defects as well as a device implementing one of these methods.

### TECHNOLOGICAL BACKGROUND OF THE INVENTION

When developing or characterizing a semiconductor device, it is useful to be able to anticipate the course of its behavior over time. This is especially true in the case of field effect transistors, whose characteristics can drift over time.

A well-known phenomenon, called the Bias Temperature Instability (BTI), describes an instability or shift in the threshold voltage V_{TH} depending on the voltage applied to the gate of the transistor V_{G}, and the temperature T. Indeed, when a first measurement I_{D}(V_{G}) is made (where I_{D} is the drain current) and then a non-zero gate voltage V_{GStress} is applied for a time t_{Stress}, a characteristic shift I_{D} (V_{G}) can be observed when the measurement I_{D}(V_{G}) is made again. This characteristic shift I_{D}(V_{G}) then results in a shift in the threshold voltage V_{TH}. Such a shift is illustrated in [FIG. 1].

A technique for measuring this shift in V_{TH} during the gate stress is already known: it is the so-called Measurement-Stress-Measurement (MSM) procedure. The stress is interspersed with an ultrafast (<10 μs) measurement I_{D}(V_{G}) such that V_{TH} extraction is possible. Indeed, the shift in the threshold voltage V_{TH} is due to the activation of electronic traps during the application of a stress voltage at the gate. During the MSM measurement, the ultrafast measurement does not give these traps time to relax as illustrated in [FIG. 2].

Thus, the MSM procedure allows BTI transients (ΔV_{TH}(t)) to be obtained as can be seen in [FIG. 3]. There, these transients can be observed in the stress phase (V_{GStress}≠0V) and recovery phase (V_{GStress}=0V) occurring just after the stress. In this example, pBTI transients will be said to be observed because the applied stress voltages are positive. Conversely, when a negative stress voltage is applied, nBTI transients are mentioned.

When developing an electronic device, it is important to be able to account for these transients. In general, a density mapping of the traps at the origin of the shift in the threshold voltage (called the CET (Capture Emission Time) mapping) is determined and, from this CET mapping, the variation in the threshold voltage as a function of the duration of the stress and the recovery time. However, the determination of such a mapping is very tedious and therefore time consuming. Furthermore, it is performed manually, which makes different mappings difficult to compare.

Moreover, due to the time required to establish such a mapping, this work is usually only done for one stress voltage and one temperature.

Therefore, there is a need for a method that allows a CET mapping to be determined quickly and automatically.

### SUMMARY OF THE INVENTION

The invention offers a solution to the previously mentioned problems, by making it possible to determine a CET mapping from experimental measurements using a genetic algorithm.

To this end, a first aspect of the invention relates to a method for determining a CET mapping characterizing the capture and emission time of traps in a transistor for a given stress voltage and a given temperature, called the optimal CET mapping, this determination being made from an experimental measurement of the time course of the change in the threshold voltage V_{TH} for the same stress voltage and the same temperature and from a distribution function of the traps, said distribution function may be defined by Nₚₐᵣ parameters, said method comprising:
an initialization phase including a step of determining Nₚₒₚ vectors having dimension Nₚₐᵣ, called an initial population, the coordinates of each vector corresponding to a value of the parameters of the distribution function,
a resolution phase including:
   a step of determining Nₚₒₚ descendant vectors, called a descendant population, this step comprising at least a crossover sub-step or a mutation sub-step;
   a step of evaluating each vector of the initial population and the descendant population from the experimental measurement of the time course of the change in the threshold voltage so as to determine, for each vector, an indicator of the fit between the course determined, for a fixed computational resolution, from the vector under consideration and the experimental measurement of this course;
   a step of selecting, from the 2Nₚₒₚ vectors of the initial population and the descendant population, the Nₚₒₚ vectors with the best fit indicator;
      the previous steps of the resolution phase being repeated successively until a first stopping condition is reached, that is a function of a number of iterations Nₗᵢₘᵢₜ and/or of the best fit indicator, the Nₚₒₚ vectors selected during the selection step becoming the initial population during each new iteration; a step of selecting the vector with the best fit indicator being implemented when this first stopping condition is reached.

By virtue of the invention, it is therefore possible to automate the determination of a mapping using a genetic algorithm. As a reminder, in the state of the art, such a map was determined manually, which made it difficult to compare mappings made by different people, or even by the same person on different samples. The automation of this task makes such comparisons possible. It also allows the determination of a plurality of mappings for different temperatures or stress levels.

Further to the characteristics just discussed in the previous paragraph, the method according to a first aspect of the invention may have one or more of the following additional characteristics, considered individually or in any technically possible combinations.

In one embodiment, the method also comprises, after the resolution phase, a refinement phase including at least one of the following steps:
a step of determining a new initial population as a function of the vector with the best fit indicator obtained during the previous resolution phase, the new population having a number of vectors N′ₚₒₚ<Nₚₒₚ;
a step of increasing the computational resolution used during the evaluation step of the resolution phase;
a step of changing the first stopping condition;
   the resolution phase being implemented again with the new initial population, the new computational resolution and the new first stopping condition; the resolution phase and refinement phase being iterated successively until a second stopping condition is reached that is a function of the fit indicator of the vector with the best fit indicator and the number of iterations of the resolution phase and the refinement phase, the CET mapping associated with the vector with the best fit indicator then being selected as the optimal CET mapping.

In one embodiment, the evaluation step of the initial population and the descendant population comprises, for each vector:
a sub-step of determining, for a fixed computational resolution, the CET mapping corresponding to the vector under consideration;
a sub-step of determining, from the mapping determined during the previous sub-step, the time course of the change in the threshold voltage;
a sub-step of comparing the time course thus determined with the experimental measurement of the time course of the change in the threshold voltage so as to determine a goodness-of-fit indicator between the course determined from the vector and the experimental measurement of this course.

In one embodiment, the distribution function of the traps is defined from at least one Gaussian, preferably two Gaussians.

In one embodiment, the coordinates of each vector correspond to a value of the normalized parameters of the distribution function.

In one embodiment, the step of determining Nₚₒₚ descendant vectors comprises a crossover sub-step and a mutation sub-step.

In one embodiment, the resolution used for the evaluation step is an adaptive step resolution.

A second aspect of the invention relates to a method for determining the activation energy of a type of defects in a transistor, the method comprising:
for a plurality of temperatures, a step of implementing a method according to a first aspect of the invention, so as to obtain, for each temperature of the plurality of temperatures, a CET mapping, the distribution function being identical for each implementation and consisting of at least one sub-distribution relating to the type of defects under consideration, a plurality of CET mappings thus being obtained;
from the plurality of CET mappings, a step of determining, as a function of temperature, the position of the maximum of the sub-distribution in a representation having the capture time on the abscissa and the emission time on the ordinate;
from the course of the position of the maximum of the sub-distribution relating to the population of defects under consideration, a step of determining the activation energy of the type of defects under consideration.

A third aspect of the invention relates to a data processing device comprising means configured to implement the method according to a first aspect or a second aspect of the invention.

A fourth aspect of the invention relates to a computer program comprising instructions which, when the program is executed by a computer, cause the computer to implement the method according to a first aspect or a second aspect of the invention.

A fifth aspect of the invention relates to a computer-readable data medium on which the computer program according to the fourth aspect of the invention is recorded.

The invention and its various applications will be better understood upon reading the following description and examining the accompanying figures.

### BRIEF DESCRIPTION OF THE FIGURES

The figures are set forth by way of indicating and in no way limiting purposes of the invention.

FIG. 1 illustrates the shift in the threshold voltage induced by the presence of defects.

FIG. 2 illustrates the so-called Measurement-Stress-Measurement procedure.

FIG. 3 illustrates the shift in the threshold voltage as a function of stress duration and recovery duration.

FIG. 4 to FIG. 7 illustrate the use of a CET mapping for determining the shift in the threshold voltage as a function of stress duration and recovery duration.

FIG. 8 shows a flowchart of a method according to a first aspect of the invention.

FIG. 9 shows an example of a fault distribution from two Gaussians.

FIG. 10 illustrates the error value as a function of the number of Gaussians N_{Gauss} used to characterize the defect distribution.

FIG. 11 shows a schematic representation of the generation of a descendant population from an initial population.

FIG. 12 illustrates a normal distribution for determining the new value of an element during the mutation sub-step.

FIG. 13 illustrates the notion of the computational resolution for a given CET mapping.

FIG. 14 shows a schematic representation of the selection of vectors for obtaining the best fit.

FIG. 15 shows a schematic representation of the new initial population composed by the vectors for obtaining the best fit.

FIG. 16 shows a flowchart of a method according to a second aspect of the invention.

FIG. 17 illustrates the course of the maximum of a sub-distribution associated with a type of defects as a function of temperature.

FIG. 18 illustrates the determination of the activation energy of defects.

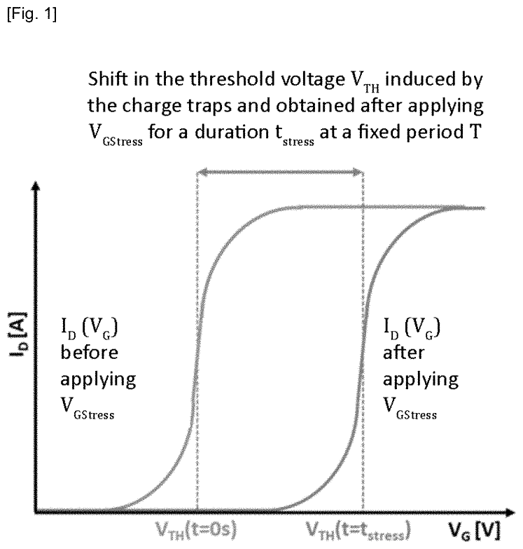

### DETAILED DESCRIPTION

Unless otherwise specified, the same element appearing on different figures has a unique reference.

Reminder on CET Mapping

In order to understand the invention, it will now be reminded how it is possible to determine, from a CET mapping, the shift in the threshold voltage V_{TH} as a function of the duration of the stress applied (for a given stress voltage and a given temperature).

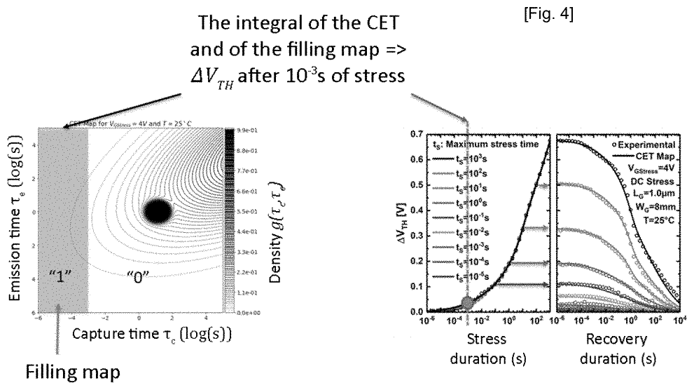

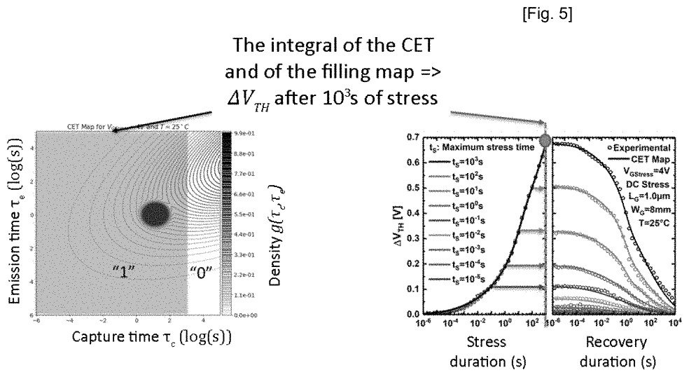

As a reminder, as illustrated in [FIG. 4] on the left, a CET mapping represents the trap density as a function of the capture time on the abscissa and the emission time on the ordinate. It is established for a given stress voltage and a given temperature. Such a mapping allows the number of activated traps to be determined as a function of the duration of applied stress. In [FIG. 4], a stress duration of 10⁻³ s was imposed and the shaded zone represents the region of the mapping corresponding to the traps activated for such a stress duration, namely the traps with a capture time less than or equal to the stress duration. By integrating the density over the region thus identified, it is possible to trace the number of activated traps and, assuming an equal contribution of all traps in the shift in the threshold voltage V_{TH}, the shift in threshold voltage V_{TH} corresponding to such a stress duration ([FIG. 4] on the right). By repeating this operation for a plurality of stress durations (for example for a duration of 10³ s in [FIG. 5]), it is possible to reconstruct the course of the shift in the threshold voltage V_{TH} as a function of this duration (left part of the graph on the right in [FIG. 4] and [FIG. 5]).

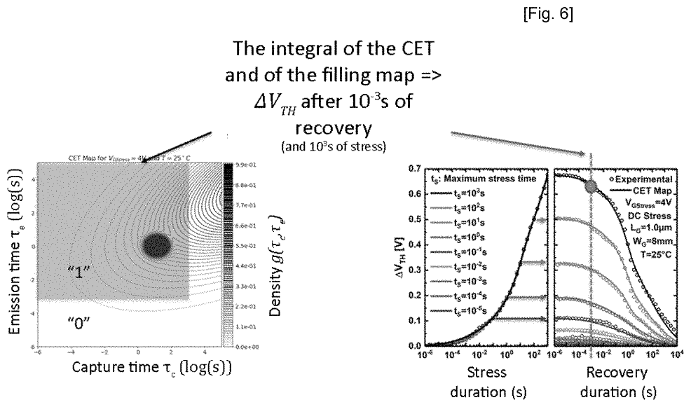

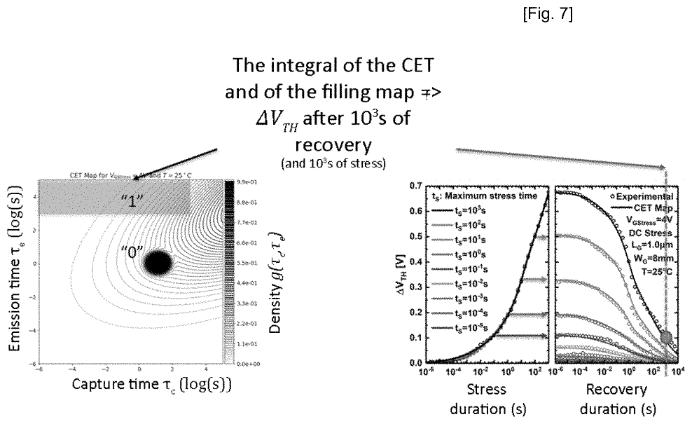

In a similar way, it is possible, from this same CET mapping, to trace the course of the number of traps still active after a duration without stress application, called hereinafter a recovery duration. For example, as illustrated in [FIG. 6], starting from the shaded zone corresponding to the maximum duration of the applied stress, it is possible to identify the mapping zone corresponding to traps that are still active after 10⁻³ s of recovery, namely traps activated during the application of the stress and which have an emission time greater than 10⁻³ s ([FIG. 6] left). By integrating the density over the region thus identified, it is possible to trace the number of traps still active and, assuming an equal contribution of all traps in the shift in the threshold voltage V_{TH}, the shift in the threshold voltage V_{TH} corresponding to such a recovery duration ([FIG. 6] right). By repeating this operation for a plurality of recovery durations (for example for a duration of 10³ s in [FIG. 7]), it is possible to reconstruct the course of the shift in the threshold voltage V_{TH} as a function of recovery duration (right part of the graph on the right in [FIG. 6] and [FIG. 7]). Furthermore, as shown by the plurality of curves on the right side of the right-hand graph in [FIG. 6] and [FIG. 7], it is possible to perform such a computation for different stress durations (here, nine different stress durations).

From the above, therefore, it is apparent that the determination of a CET mapping allows the course of the shift in the threshold voltage V_{TH} to be traced as a function of the stress duration and recovery duration. This also means that a CET mapping can be evaluated by comparing the prediction of this course determined from the CET mapping with an experimental measurement of this course, for example as a function of the goodness-of-fit obtained.

Method for Determining an Optimal CET Mapping

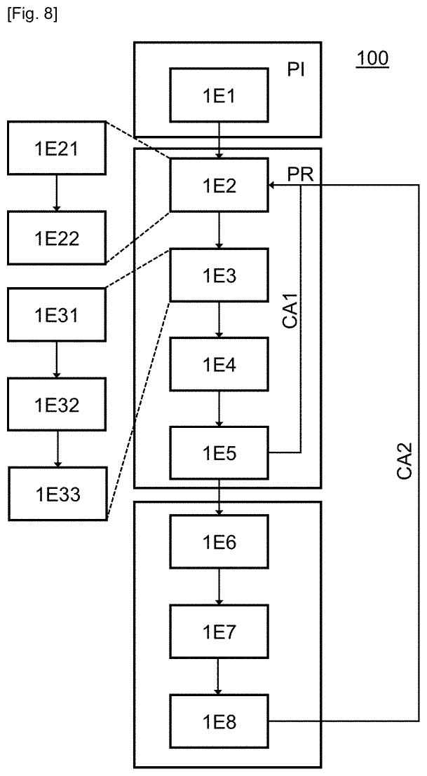

A first aspect of the invention illustrated in [FIG. 8] relates to a method 100 for determining an optimal CET mapping, in other words, a mapping characterizing the capture and emission time of traps in a semiconductor device as previously set forth. As detailed above, a CET mapping is relating to a given stress voltage and a given temperature. Also, the determination according to the invention is made for a given stress voltage and a given temperature. However, the method 100 for determining an optimal CET mapping may be repeated for several stress voltages and/or several temperatures so as to obtain a plurality of optimal CET mappings, each optimal CET mapping corresponding to a given stress voltage and a given temperature.

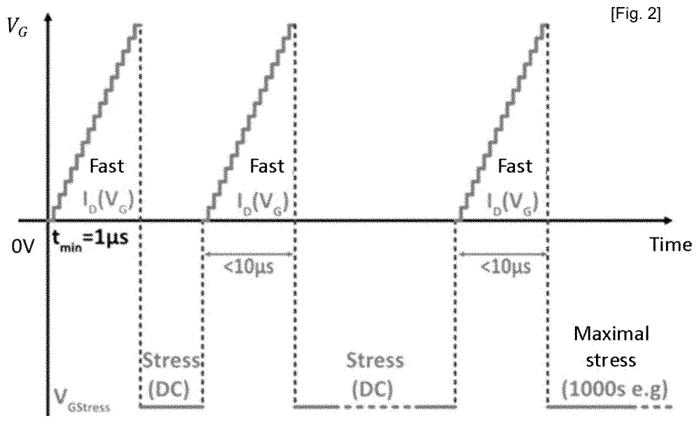

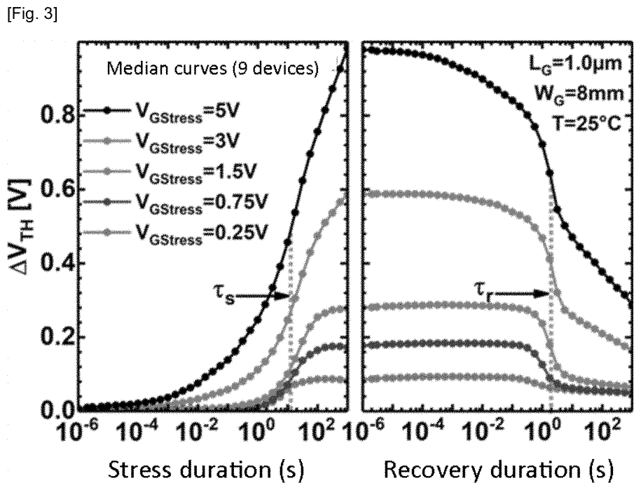

In order to be able to determine this optimal CET mapping using a method 100 according to the invention, it is necessary to have an experimental measurement of the time course of the change in the threshold voltage V_{TH} corresponding to the given stress voltage and the given temperature, namely, the stress voltage and the temperature for which it is desired to determine the optimal CET mapping. As mentioned above, such a measurement can be used to evaluate the prediction of the time course of the change in the threshold voltage V_{TH} (hereafter prediction) made with a given CET mapping and retain or not the mapping thus evaluated. The details about this evaluation will be given in the following. The measurement can for example be carried out using the Measurement-Stress-Measurement technique described in the introduction to the description and well known to the skilled person (cf. [FIG. 2]).

The determination is also made from at least one distribution function of the traps, said distribution function being characterized by Nₚₐᵣ parameters. For a given value of the Nₚₐᵣ parameters, this distribution makes it possible to obtain a CET mapping which has then to be evaluated. Thus, a CET mapping is given by a distribution function characterized by Nₚₐᵣ parameters and by a set of values of said parameters, represented in the following by a vector having dimension Nₚₐᵣ. Also, as the distribution function does not vary during the method, mention will be made indifferently of the evaluation of a CET mapping or of the evaluation of the value of the parameters associated with the latter.

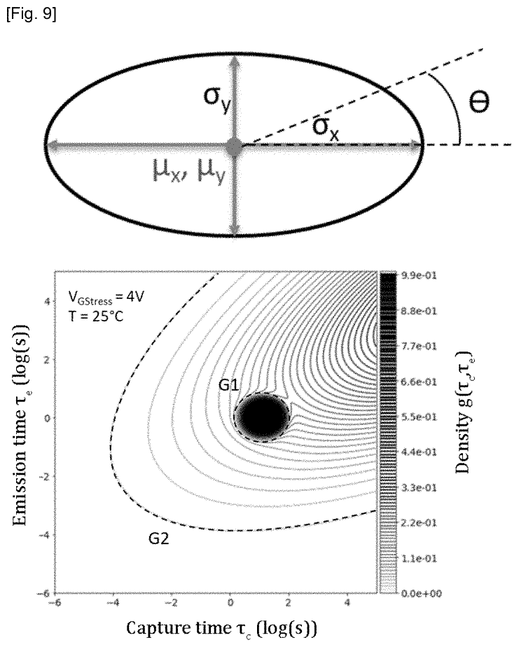

In one exemplary embodiment illustrated in [FIG. 9], the distribution is defined using two Gaussians G₁, G₂. Each Gaussian is defined by the following parameters: the coordinates of the center of the Gaussian denoted as μₓ and μ_{y}, the standard deviations denoted as σₓ and σ_{y}, the amplitude denoted as A and the lateral orientation denoted as θ. Thus, each Gaussian is determined by six parameters, and the distribution can be characterized by Nₚₐᵣ parameters with Nₚₐᵣ=2×6=12. More generally, when a plurality of Gaussians are used to define the distribution, then Nₚₐᵣ=6×N_{Gauss} where N_{Gauss} is the number of Gaussians used.

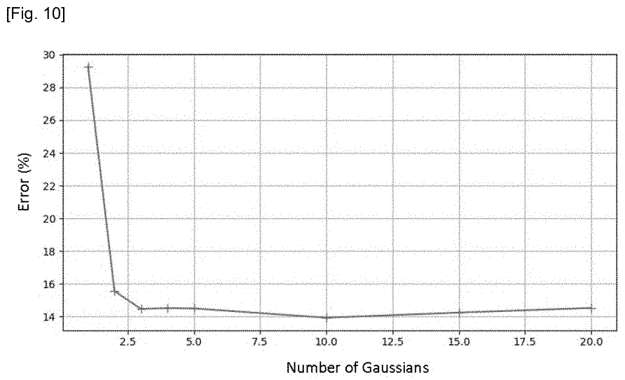

However, the greater the number of Gaussians, the greater the computational power required to evaluate each CET mapping. However, a larger number of Gaussian distributions does not necessarily lead to improved accuracy in the determination of the CET mapping as shown in [FIG. 10]. This figure illustrates, for a particular example of material, the value of the error (namely, the difference between the prediction made with the optimal mapping determined using a method 100 according to the invention and the experimental measurement) as a function of the number of Gaussians N_{Gauss} used. It is clearly apparent from this figure that a number of Gaussians greater than three does not necessarily improve the accuracy in the determination of the CET mapping.

In one embodiment, the number of Gaussians used is determined by the number of trap types (or trap populations) present in the material. For example, if two types of traps are present (thus constituting two trap populations), then two Gaussians will be used.

In one embodiment, the Gaussians used are two-dimensional Gaussians having the following form:

$$G ( x , y ) = A \cdot exp [ - \frac{1}{2} \cdot {( \frac{( x - {µ}_{x} ) \cdot cos ( θ ) - ( y - {µ}_{y} ) \cdot sin ( θ )}{{σ}_{x}} )}^{2} - \frac{1}{2} \cdot {( \frac{( x - {µ}_{x} ) \cdot sin ( θ ) + ( y - {µ}_{y} ) \cdot cos ( θ )}{{σ}_{y}} )}^{2} ] \qquad [ Math . 1 ]$$

Of course, other functions can be used to define the distribution function without changing the principles stated above. For example, it is also possible to use a two-dimensional Lorentzian if it is considered that the trap densities are more localized:

$$L ( x , y ) = A / [ 1 + {( \frac{( x - {µ}_{x} ) \cdot cos ( θ ) - ( y - {µ}_{y} ) \cdot sin ( θ )}{{σ}_{x}} )}^{2} + {( \frac{( x - {µ}_{x} ) \cdot sin ( θ ) + ( y - {µ}_{y} ) \cdot cos ( θ )}{{σ}_{y}} )}^{2} ] \qquad [ Math . 2 ]$$

It is also possible to use pseudo Voigt function which is based on a linear combination of the last two functions, adding the seventh parameter η in the Nₚₐᵣ parameters, and which is defined by:

V(x,y)=η·L(x,y)+(1−η)·G(x,y) [Math. 3]

This last function has the advantage of allowing a distribution profile to be obtained, that can be Gaussian (η=0), Lorentzian (η=1) or in between (0<η<1), which makes it possible to improve the fit and thus better reproduce the experimental results. On the other hand, this requires the fit of an additional parameter r, which complicates the convergence and requires a higher computational power, especially because of the presence of two functions to be computed (G and L).

Initialization Phase

In order to determine an optimal CET mapping, the method 100 according to the invention includes an initialization phase PI including a step 1E1 of determining Nₚₒₚ vectors having dimension Nₚₐᵣ, called the initial population, the coordinates of each vector corresponding to a value of the parameters of the distribution function, preferably a normalized value thereof, and thus to a CET mapping. Each CET mapping thus obtained is only a candidate CET mapping, and only one CET mapping (called the optimal TEC map) from these or their descendants will be retained at the end of the method according to the invention.

Preferably, during the initialization phase PI, the number of vectors Nₚₒₚ is between 500 and 1500, such a value making it possible to obtain a good compromise between the computation time and the risk of determining an optimal solution actually corresponding to a local minimum.

In one embodiment, the Nₚₒₚ initial vectors are obtained using a Latin Hypercube Sampling (LHS) method, by random sampling (the coordinates of each vector are randomly drawn) or by orthogonal sampling.

As already mentioned, the larger the number of vectors Nₚₒₚ the lower the chances of determining an optimal solution corresponding to a local minimum. On the other hand, a large number of Nₚₒₚ vectors implies a high computational power necessary to determine the optimal solution. There is thus a compromise to be made between the number of Nₚₒₚ vectors and the risk that the determination of the optimal solution leads to a local minimum. As will be seen later, in one particularly advantageous embodiment, the method 100 according to the invention makes it possible to eliminate, or at least limit, such a compromise by reducing the number of vectors as the risk that the optimal solution corresponds to a local minimum decreases.

Resolution Phase

The method 100 according to the invention also includes a resolution phase PR. During this resolution phase, a provisional optimal CET mapping with the best match with the experimental measurements (compared to all other CET mappings) will be determined using a genetic algorithm.

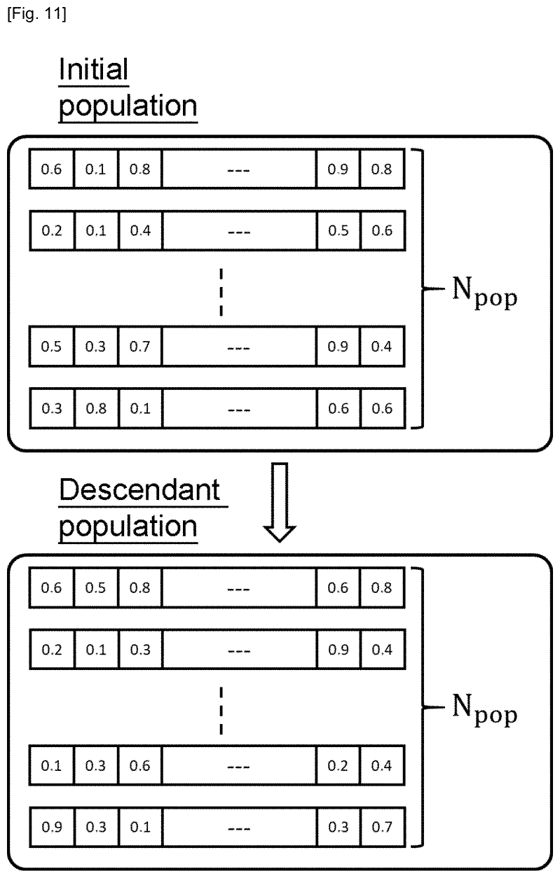

For this, this resolution phase PR includes a step 1E2 of determining Nₚₒₚ descendant vectors, called the descendant population. In one embodiment, this determination step 1E2 comprises at least a crossover sub-step 1E21 or a mutation sub-step 1E22. Although known to those skilled in genetic algorithms, the crossover and mutation steps 1E21, 1E22 will now be described. A schematic representation of the step 1E2 of determining Nₚₒₚ descendant vectors is provided in [FIG. 11]. For further details, the reader can refer to one of the many books on the subject, for example X. Yu and M. Gen, Introduction to Evolutionary Algorithms. Springer Science & Business Media, 2010.

In one exemplary embodiment, the first crossover sub-step 1E21 comprises determining two new vectors, called child vectors, from two vectors of the initial population, called parent vectors. Of course, the coordinates of the child vectors are not determined randomly, but inherited from the parent vectors. For example, by denoting the first parent as P₁, the second parent as P₂, the first child as E₁ and the second child as E₂, the children can be obtained using the following relationship:

$$\{ \begin{matrix}{E}_{1} = α {P}_{1} + ( 1 - α ) {P}_{2} \\ {E}_{2} = α {P}_{2} + ( 1 - α ) {P}_{2}\end{matrix} \qquad [ Math . 4 ]$$

with α a vector having dimension Nₚₐᵣ whose coefficients are between zero (0) and one (1). It will be noted that 1 appears in bold because it is a vector having dimension Nₚₐᵣ whose coefficients are all equal to 1. Of course, other crossover methods can be used and this is therefore only an example for illustrating the invention.

The vectors involved in each crossover can be chosen in a purely stochastic way, but also by means of other methods, such as the so-called “roulette wheel” method, the so-called “elitist” method, or even the tournament selection method. Preferably, the method used is the roulette wheel method.

In one exemplary embodiment, the second mutation sub-step 1E22 comprises applying to the vectors of the initial population and/or the descendant population a random change at one or more of their coordinates. This sub-step 1E22 can thus be performed after the crossover sub-step 1E21 in which case, it will preferably be implemented on the vectors of the descendant population only. This second sub-step 1E22 may also be implemented in place of the crossover sub-step 1E21. Preferably, both the crossover sub-step 1E21 and the mutation sub-step 1E22 are implemented.

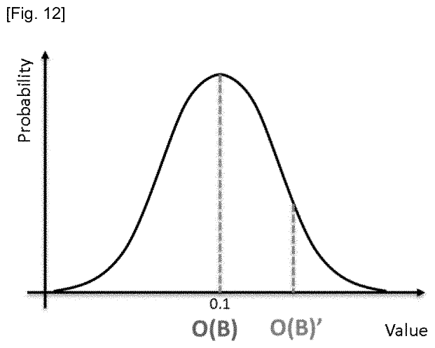

During this mutation sub-step 1E22, each vector may have one or more of its coordinates modified. In one exemplary embodiment, the probability for a coordinate to be modified is between 0.01 and 0.3, preferably between 0.01 and 0.05. Preferably, the probability of a value being modified is chosen such that the majority of vectors (namely, more than 50% of the vectors) have only one coordinate affected when implementing the mutation sub-step 1E22. In one embodiment, when a value is modified, the new value is drawn with a probability that follows a normal distribution centered on the value before modification (cf. [FIG. 12] where O(B) is the initial value (in this example equal to 0.1) and O(B)′ is the new value, the curve illustrating the normal distribution used to determine this new value).

The resolution phase PR also includes a step 1E3 of evaluating each vector of the initial population and the descendant population from the experimental measurement of the time course of the change in the threshold voltage V_{TH} so as to determine, for each vector, a goodness-of-fit indicator between the course determined from the vector and the experimental measurement of this course. In other words, each CET mapping (corresponding to a vector) is used to determine the time course of the change in threshold voltage V_{TH} as previously described. The course thus determined is then compared to experimental measurements of the same course.

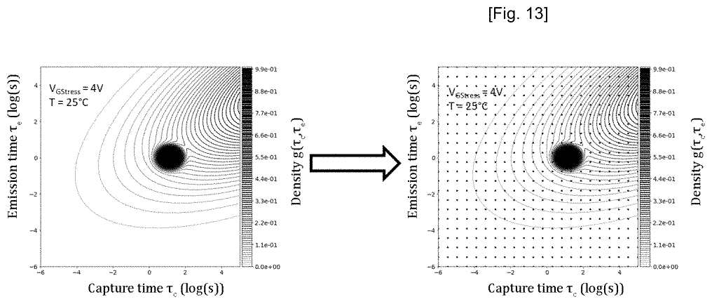

As illustrated in [FIG. 13], in order to be able to determine this course, the CET mapping is discretized, namely it is computed only for some values of the capture and emission times of the traps, the values for which the mapping is computed being given by a computational resolution (given by the black dots in [FIG. 13] on the right), this computational resolution being fixed for a given PR resolution phase. Preferably, the computational resolution is greater than or equal to 1 point per decade, or even 4 points per decade. However, it is also possible to perform the first iterations of the resolution phase PR (and thus of the evaluation step 1E3) with a computational resolution lower than that.

Of course, the higher the computational resolution, the better the evaluation of the CET mapping. However, a high computational resolution requires high computational power and/or long computation times. Therefore, the choice of the computational resolution requires a compromise between the accuracy in the evaluation of the CET mapping and the computational power necessary for this evaluation. It will be shown in the following that, in one particularly advantageous embodiment, the method 100 according to the invention makes it possible to eliminate, or at least reduce, this compromise by modifying the computational resolution during the various iterations of the resolution phase PR.

In one embodiment, the evaluation step 1E3 comprises a sub-step 1E31 of determining, for a fixed computational resolution, the CET mapping corresponding to the vector under consideration. It also includes a sub-step 1E32 of determining, from the CET mapping thus determined, the time course of the change in the threshold voltage V_{TH} (the method allowing this determination has already been introduced and is illustrated in [FIG. 4] to [FIG. 7]). It further comprises a sub-step 1E33 of comparing the time course of the change in the threshold voltage V_{TH} determined using the CET mapping under consideration and the experimental measurement of this course so as to determine a goodness-of-fit indicator of these two courses. Thus, the closer the time course of the change in the threshold voltage V_{TH} determined using the CET mapping under consideration is to the experimental measurement, the lower the goodness-of-fit indicator.

In one exemplary embodiment, the goodness-of-fit indicator is determined using the following expression (corresponding to a least square method):

E=\sqrt{Σᵢ₌₁ⁿ(Y_{obs,i}−Y_{model,i})²/n} [Math. 6]

where E is the goodness-of-fit indicator, n is the number of experimental points under consideration, Y_{obs,i} is the value of the i^{th} experimental value, and Y_{model,i} is the value determined using the corresponding CET mapping.

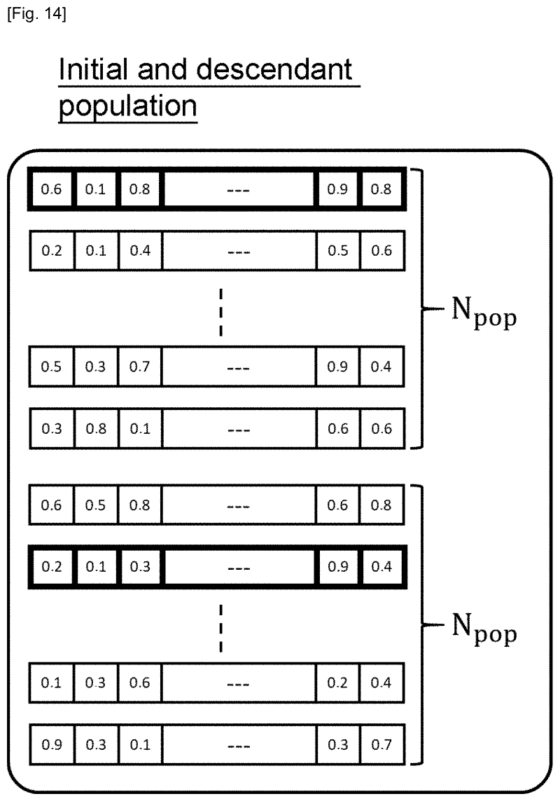

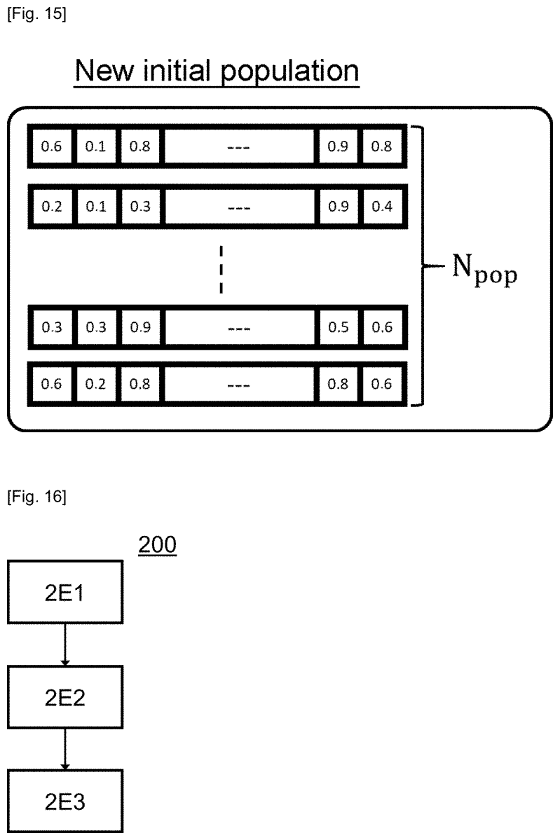

At the end of the evaluation step 1E3, it is possible to compare the vectors with each other according to the goodness-of-fit determined for each of them and to select the vectors with the best fit. To this end, the method according to the invention comprises a step 1E4 of selecting from the 2Nₚₒₚ vectors of the initial population (Nₚₒₚ vectors) and of the descendant population (Nₚₒₚ vectors), the Nₚₒₚ vectors with the best fit indicator. An illustration of this step is provided in [FIG. 14] in which the selected vectors appear in bold. As illustrated in [FIG. 15], these selected vectors will then constitute the new initial population for the next iteration of the previous steps.

Steps 1E2, 1E3, 1E4 are repeated until a first stopping condition CA1 that is a function of a number of iterations Nₗᵢₘᵢₜ and/or the best fit indicator is reached, with the Nₚₒₚ vectors selected in the selection step 1E4 becoming the initial population during each new iteration.

In one embodiment, the first stopping condition CA1 is reached when, in absolute value, the difference between the best fit indicator of the previous iteration and the best fit indicator of the current iteration is lower than a predetermined threshold. This condition has the advantage of not continuing the resolution if no significant improvement of the fit indicator is observed between successive iterations. On the other hand, it is possible that a plateau is reached before an improvement occurs afterwards. In such a case, the previous stopping condition has the risk of prematurely ending the determination of the temporary optimal mapping.

In one embodiment, the first stopping condition CA1 is reached when the number of iterations is equal to Nₗᵢₘᵢₜ and, preferably, Nₗᵢₘᵢₜ is between 500 and 5000.

In one embodiment, the first stopping condition CA1 is reached when (condition A) the number of iterations is equal to Nₗᵢₘᵢₜ or when (condition B) the number of iterations is greater than or equal to N′ₗᵢₘᵢₜ<Nₗᵢₘᵢₜ and when (condition C), in absolute value, the difference between the best fit indicator of the previous iteration and the best fit indicator of the current iteration is less than a predetermined threshold (namely, A or (B and C)).

When the first stopping condition CA1 is reached, the method according to the invention includes a step E5 of selecting the coordinates of the vector with the best fit indicator. Thus, the resolution phase makes it possible to determine a vector whose coordinates correspond to a CET mapping that allows a good match between the threshold voltage V_{TH} determined using said CET mapping and that measured experimentally, called a temporary optimal CET mapping. Of course, when the optional phase that will now be described is not implemented, this temporary optimal CET mapping is considered as the optimal CET mapping.

The Refinement Phase (Optional)

In one embodiment, in order to further refine the determination of the CET mapping, the method 100 according to the invention also includes a third phase, called the refinement phase PA. This phase PA aims at determining a new computational resolution, a new population and/or a new first stopping condition CA1 that can be used during a new iteration of the resolution phase PR. In particular, by reducing the population of the resolution phase PR and/or by reducing the number of iterations during the resolution phase PR, it is possible to increase the computational resolution in the resolution phase PR, for example to reach a resolution for which a CET mapping is deemed significant.

In one embodiment, this refinement phase PA includes a step 1E6 of determining a new initial population that is a function the vector with the best fit indicator obtained during the previous resolution phase PR, the new population having a number of vectors Nₚₒₚ<Nₚₒₚ with Nₚₒₚ the number of vectors used in the previous iteration of the resolution phase PR. The population thus obtained is reduced with respect to the population of the previous resolution PR phase. This reduction in the population size is made possible by the fact that this population is determined from a vector allowing a relatively good match with the experimental measurements to be obtained, which limits the risk that this reduction in the population size leads to a local minimum.

In one embodiment, this phase PA includes a step 1E7 of increasing the computational resolution used during step 1E3 of evaluating the resolution phase PR. In one exemplary embodiment, during this step 1E7, this computational resolution is increased by 1 point/decade of time. Of course, this is only an example and this increase may be higher in other cases. Preferably, this step is implemented when a step 1E6 of determining a new initial population is also implemented. Thus, as the population is reduced during step 1E6 of determining a new population, it is possible to increase the resolution used for the computation of the CET mapping.

It is also possible to modify the first stopping condition CA1 used during the resolution phase in order to be able to implement the next iteration of the resolution phase RP with a higher computational resolution. Also, in one embodiment, the refinement phase also includes a step 1E8 of modifying the first stopping condition CA1.

In one exemplary embodiment, the maximum iteration number Rₗᵢₘᵢₜ is computed as a function of the maximum iteration number defined during the initialization phase PI and denoted as Nₗᵢₘᵢₜ^{initial}, especially using the following expression:

Nₗᵢₘᵢₜ=Nₗᵢₘᵢₜ^{initial}/Rⁿ [Math. 7]

where R is the computational resolution per decade used and n is a fixed decay factor. In one embodiment, n is an integer between 1 (inclusive) and 5 (inclusive). Preferably, n is equal to 1. Of course, Nₗᵢₘᵢₜ being an integer, only the rounding or the integer part of the result thus obtained will be taken into account.

Thus, at the end of the refinement phase PA, a new resolution, a new population and/or a new stopping condition have been determined and can be used during a new iteration of the resolution phase PR. Also, at the end of the refinement phase PA, the resolution phase PR is again implemented with the new resolution, the new initial population and/or the new stopping condition.

Thus, in this embodiment, the resolution phase PR and the refinement phase PA are iterated successively until a second stopping condition CA2 that is a function of the computational resolution is reached. In one embodiment, the second condition holds when the computational resolution reached is equal to a desired computational resolution denoted as Rₘₐₓ. In one embodiment, the desired computational resolution Rₘₐₓ is the resolution to be reached for the extracted CET mappings to be significant. In one embodiment, a CET mapping is considered significant when its resolution is greater than or equal to 7 points/time decade, preferably greater than or equal to 10 points/time decade, or even greater than or equal to 15 points/time decade, or even greater than or equal to 20 points/time decade. Once this second stopping condition CA2 is reached, the CET mapping associated with the vector with the best fit indicator is then selected as the optimal CET mapping.

The method 100 according to the invention thus makes it possible to automate the determination of a CET mapping using a genetic algorithm. As a reminder, in the state of the art, such a map was determined manually, which made it difficult to compare CET mappings made by different people, or even by the same person on different samples. The automation of this task enabled by the method 100 according to the invention makes such comparisons possible. Moreover, the manual determination of a CET mapping is very tedious and therefore very long. Such a mapping is therefore generally performed for a given temperature and stress voltage, but very rarely for several values of these parameters. Again, the automation of this task enabled by the method 100 according to the invention makes it possible to determine a plurality of CET mappings for different temperatures or stress voltages.

One possible application is the determination of the activation energy of defects from a plurality of CET mappings performed for different temperatures.

Method for Determining the Activation Energy of Defects in a Transistor

To this end, a second aspect of the invention illustrated in [FIG. 16] relates to a method 200 for determining the activation energy of a type of defects in a transistor. The method 200 according to a second aspect of the invention comprises, for a plurality of temperatures, a step 2E1 of implementing a method 100 according to a first aspect of the invention, so as to obtain, for each temperature of the plurality of temperatures, a CET mapping. Moreover, during this step 2E1, the distribution function is identical for each implementation. It further consists of at least one sub-distribution relating to the type of defects under consideration, a plurality of CET mappings being thus obtained. In the example given in [FIG. 9], the distribution consists of two sub-distributions in the form of two Gaussians, the first Gaussian being relating to a first population of defects (or type of defects) and the second Gaussian being relating to a second population of defects (or type of defects).

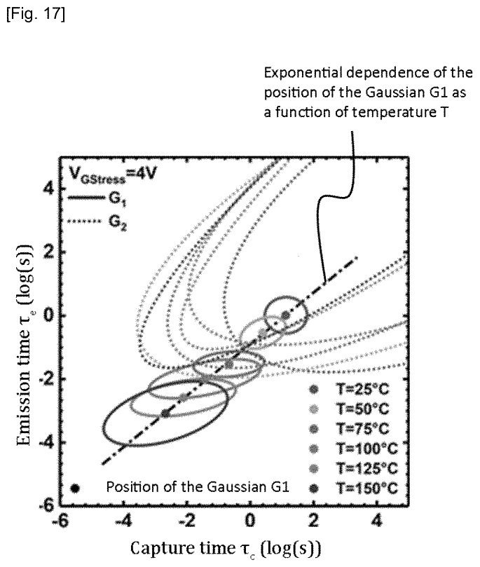

The method 200 according to a second aspect of the invention also comprises, from the plurality of CET mappings, a step 2E2 of determining, as a function of temperature, the position of the maximum of the sub-distribution in a representation having as axes the capture time (for example on the abscissa) and the emission time (for example on the ordinate). This step 2E2 is illustrated in [FIG. 17] which shows the course of a first Gaussian (denoted as G1) relating to a first type of defects and a second Gaussian (denoted as G2) relating to a second type of defects as a function of temperature. From this course, it is possible to follow the position of each of these sub-distributions as a function of temperature (see the dotted line for the course of the position of the maximum of the first Gaussian G1).

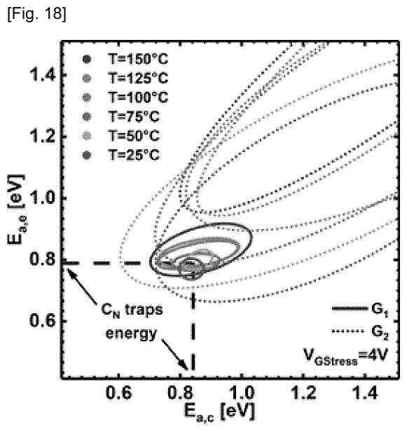

Finally, the method 200 according to a second aspect of the invention comprises, from the course of the position of the maximum of the sub-distribution relating to the population of defects under consideration, a step 2E3 of determining the activation energy of the type of defects under consideration. This determination is illustrated in [FIG. 18].

More particularly, the activation energies are obtained by converting the time scales of the different extracted CET mappings to activation energy scales. This conversion is done by means of the following equation:

$${τ}_{c / e} = {τ}_{0} exp ( \frac{{E}_{a , c / e}}{{k}_{B} T} ) \qquad [ Math . 8 ]$$

where E_{a,c/e} is the activation energy associated with capture or emission, τ_{c/e} is the capture or emission time constant, k_{B} is the Boltzmann constant, T is the temperature, and τ₀ is determined by solving the following equation:

$$\frac{{T}_{1}}{{T}_{2}} = log ( \frac{{τ}_{1}}{{τ}_{0}} ) / log ( \frac{{τ}_{2}}{{τ}_{0}} ) \qquad [ Math . 9 ]$$

where τ₁ (respectively τ₂) is a time constant obtained at temperature T₁ (respectively T₂) and τ₀ is the elastic tunneling time between traps and carriers in the semiconductor under consideration.

For more details, the reader may refer for example to the following documents: K. Puschkarsky, H. Reisinger, C. Schlünder, W. Gustin and T. Grasser, “Fast acquisition of activation energy mappings using temperature ramps for lifetime modeling of BTI,” 2018 48th European Solid-State Device Research Conference (ESSDERC), Dresden, 2018, pp. 218-221, doi: 10.1109/ESSDERC.2018.8486855, and K. Puschkarsky, H. Reisinger, C. Schlünder, W. Gustin and T. Grasser, “Voltage-Dependent Activation Energy Mappings for Analytic Lifetime Modeling of NBTI Without Time Extrapolation,” in IEEE Transactions on Electron Devices, vol. 65, no. 11, pp. 4764-4771, November 2018, doi: 10.1109/TED.2018.2870170.

A Device for Determining a CET Mapping or Activation Energy of Defects in a Transistor

The method 100, 200 according to a first aspect of the invention or a second aspect of the invention may be implemented by a device comprising a computation means (for example, a processor) associated with a memory on which the instructions and data necessary for implementing the method 100, 200 under consideration, are stored. In one embodiment, the device also comprises an input means allowing the user to input the data necessary for the implementation of the method 100, 200 considered. In one embodiment, the device also comprises a display means enabling the user to display the progress and/or the results of the method 100, 200 under consideration. In one embodiment, the device also comprises acquisition means necessary for the acquisition of experimental data used during the implementation of the method 100, 200 under consideration.

1. A method for determining a CET mapping characterizing the capture and emission time of traps in a transistor for a given stress voltage and a given temperature, called an optimal CET mapping, said determining being made from an experimental measurement of a time course of a change in a threshold voltage V_{TH} for a same stress voltage and a same temperature and from a distribution function of the traps, said distribution function defined by Nₚₐᵣ parameters, said method comprising:
an initialization phase including a step of determining Nₚₒₚ vectors having dimension Nₚₐᵣ, called an initial population, the wherein coordinates of each vector correspond to a value of the parameters of the distribution function;
a resolution phase including:
a step of determining Nₚₒₚ descendant vectors, called a descendant population, said step of determining Nₚₒₚ descendant vectors comprising at least a crossover sub-step and/or a mutation sub-step;
a step of evaluating each vector of the initial population and the descendant population from the experimental measurement of the time course of the change in the threshold voltage so as to determine, for each vector, an indicator of a fit between the course determined, for a fixed computational resolution, from the vector under consideration and the experimental measurement of this course;
a step of selecting, from the 2Nₚₒₚ vectors of the initial population and the descendant population, the Nₚₒₚ vectors with the best fit indicator;
the previous steps of the resolution phase being repeated successively until a first stopping condition that is a function of a number of iterations Nₗᵢₘᵢₜ and/or of the best fit indicator is reached, the Nₚₒₚ vectors selected during the selection step becoming the initial population during each new iteration; a step of selecting the vector with the best goodness-of-fit indicator being implemented when said first stopping condition is reached.

2. The method according to claim 1, comprising, at the end of the resolution phase, a refinement phase including at least one of the following steps:
a step of determining a new initial population as a function of the vector with the best fit indicator obtained during the previous resolution phase, the new population having a vector number N′ₚₒₚ<Nₚₒₚ;
a step of increasing the computational resolution used during the step of evaluating the resolution phase;
a step of modifying the first stopping condition;
the resolution phase being implemented again with the new initial population, the new computational resolution and/or the new first stopping condition; the resolution phase and the refinement phase being iterated successively until a second stopping condition that is a function of the computational resolution used during the iteration of the resolution phase, the CET mapping associated with the vector with the best fit indicator then being selected as the optimal CET mapping.

3. The method according to claim 1, wherein the step of evaluating each vector of the initial population and the descendant population comprises, for each vector:
a sub-step of determining, for a fixed computational resolution, the CET mapping corresponding to the vector under consideration;
a sub-step of determining, from the mapping determined during the previous sub-step, the time course of the change in the threshold voltage;
a sub-step of comparing the time course thus determined to the experimental measurement of the time course of the change in the threshold voltage so as to determine a goodness-of-fit indicator between the course determined from the vector and the experimental measurement of this course.

4. The method according to claim 1, wherein the distribution function of the traps is defined from at least one Gaussian.

5. The method according to claim 1, wherein the coordinates of each vector of the initial population and the descendant population correspond to a value of the normalized parameters of the distribution function.

6. The method according to claim 1, wherein the step of determining Nₚₒₚ descendant vectors comprises a crossover sub-step and a mutation sub-step.

7. The method according to claim 1, wherein the resolution used for the evaluation step (1E3) is an adaptive step resolution.

8. A method for determining the activation energy of a type of defects in a transistor, the method comprising:
for a plurality of temperatures, a step of implementing a method according to claim 1, so as to obtain, for each temperature of the plurality of temperatures, a CET mapping, the distribution function being identical for each implementation and consisting of at least one sub-distribution relating to the type of defects under consideration, a plurality of CET mappings thus being obtained;
from the plurality of CET mappings, a step of determining, as a function of temperature, the position of the maximum of the sub-distribution in a representation having the sensor time as the abscissa and the emission time as the ordinate;
from the course of the position of the maximum of the sub-distribution relating to the population of defects under consideration, a step of determining the activation energy of the type of defects under consideration.

9. A data processing device comprising a processor configured to implement the method according to claim 1.

10. (canceled)

11. A non-transitory computer-readable data medium on which a computer program comprising instructions which, when the instructions are executed by a computer, cause the computer to implement the method according to claim 1.

12. The method according to claim 4, wherein the distribution function of the traps is defined from two Gaussians.
